(19) United States
(12) Patent Application Publication
(10) Pub. No.: US 2008/0308036 A1
(43) Pub. Date: Dec. 18, 2008

(54) VAPOR-PHASE GROWTH APPARATUS AND VAPOR-PHASE GROWTH METHOD

(76) Inventors: Hideki ITO, Shizuoka (JP); Hironobu Hirata, Shizuoka (JP); Shinichi Mitani, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/137,843

(22) Filed: Jun. 12, 2008

(30) Foreign Application Priority Data
Jun. 15, 2007 (JP) 2007-158884
Jul. 25, 2007 (JP) 2007-192899

(51) Int. Cl. C30B 35/00; C30B 23/02

(52) U.S. Cl. 117/88; 118/724

(57) ABSTRACT

There is provided a vapor-phase growth apparatus which shortens a temperature decrease time of a wafer substrate after an epitaxial growth step to make it easy to realize a high throughput in film formation of an epitaxial layer. The vapor-phase growth apparatus includes a gas supply port formed in a top portion of a reactor, a gas distribution plate arranged in the reactor, a discharge port formed in a bottom portion of the reactor, an annular holder on which a semiconductor wafer is placed to face the gas distribution plate. A separation distance between the gas distribution plate and the annular holder is set such that a cooling gas which flows downward from the gas supply port through the gas distribution plate to decrease the temperature is in a laminar flow state on a surface of the semiconductor wafer or a surface of the annular holder.

### CROSS-REFERENCE TO RELATED APPLICATION

This application is based upon and claims the benefit of priority from Japanese Patent Applications No. 2007-158884, filed on Jun. 15, 2007 and No. 2007-192899, filed on Jul. 25, 2007 the entire contents of which are incorporated herein by reference.

### FIELD OF THE INVENTION

The present invention relates to a vapor-phase growth apparatus and a vapor-phase growth method. In particular, the present invention relates to a vapor-phase growth apparatus and a vapor-phase growth method which makes it easy to realize a high throughput in deposition of a vapor-phase grown layer of a semiconductor substrate.

### BACKGROUND OF THE INVENTION

For example, in manufacturing of a semiconductor device on which an ultrahigh-speed bipolar device, an ultrahigh-speed CMOS device, a power MOS transistor, and the like are formed, an epitaxial growth technique for a monocrystalline layer which is controlled in impurity concentration, film thickness, crystal defect, or the like is essential to improve the performance of the device.

An epitaxial growth apparatus grows a monocrystalline thin film on a surface of a semiconductor substrate such as a silicone wafer or a compound semiconductor wafer for use as a substrate of a semiconductor device. Such an epitaxial growth apparatus includes an epitaxial growth apparatus of a batch processing type which can process a large number of wafers at once and a single wafer processing type which processes wafers one by one. Since the batch processing epitaxial growth apparatus can process a large number of wafers at once, the manufacturing cost of epitaxial wafers can be reduced with a high throughput. On the other hand, the single-wafer-processing type epitaxial growth apparatus can cope with an increase in diameter of a wafer and is good in uniformity of a film thickness or the like of the epitaxial grown layer.

In recent years, with a high integration density, a high performance, multifunctionalization, and the like of a semiconductor device using a silicon wafer, a silicone epitaxial wafer is expanded in application. For example, in manufacture of a semiconductor device on which a memory circuit composed of CMOS devices is mounted, a memory capacity is at, for example, a gigabit level. In order to secure the manufacturing yield, an epitaxial wafer is frequently used which has a silicon epitaxial layer having a thickness of, for example, about 10 μm and which is better in crystallinity than that of a bulk wafer. A so-called distorted silicon epitaxial layer having, for example, a silicon-germanium alloy layer which makes it easy to micropattern elements and realize an ultrahigh-speed CMOS device is expected to be actually used. In a semiconductor device having a high-withstand-voltage device such as a power MOS transistor, an epitaxial wafer having a silicon epitaxial layer with a high specific resistance and a film thickness of, for example, about 50 to 100 μm.

In these circumstances, a diameter of a wafer increases, for example, 300 mmφ, a film thickness of an epitaxial grown layer must be uniformly controlled at high accuracy over a wafer surface, and the radio of the single-wafer-processing type epitaxial growth apparatus increases. However, as described above, since the single-wafer-processing type epitaxial growth apparatus cannot perform a batch process for wafers, the throughput of the epitaxial growth apparatus is in general lower than that of the batch processing epitaxial growth apparatus. Also, it is difficult to reduce the manufacturing cost of an epitaxial wafer. As the single-wafer-processing type epitaxial growth apparatus, epitaxial growth apparatuses having various structures which increase epitaxial growth rates are disclosed (for example, see JP-A No. 11-67675(KOKOAI)).

### SUMMARY OF THE INVENTION

In the single-wafer-processing type epitaxial growth apparatus disclosed in JP-A No. 11-67675, a growth rate of, for example, a silicon epitaxial layer can be increased to about 10 μm/min. In the growth of the silicon epitaxial layer, a temperature of a wafer must be set to a high temperature of 1000° C. to 1200° C. For this reason, in order to increase a throughput in manufacture of an epitaxial wafer, it is important to shorten a processing time for an increase/decrease in temperature of the wafer between a room temperature and the growth temperature. Furthermore, since the epitaxial layer is a monocrystalline layer, it is required to prevent crystal defects from occurring.

However, in a conventional single-wafer-processing type epitaxial growth apparatus, in particular, a processing time in a decrease in temperature of a wafer after growth on an epitaxial layer is difficult to be shortened. The temperature-decrease processing disadvantageously works as a serious bottleneck for a high throughput in manufacture of an epitaxial wafer.

It is an object of the present invention to provide a vapor-phase growth apparatus and a vapor-phase growth method which shorten a temperature-decrease time after the vapor-phase growth step to make it easy to realize a high throughput in deposition of a vapor-phase grown layer.

In order to achieve the above object, a vapor-phase growth apparatus according to one embodiment of the present invention includes a gas supply port formed in an upper portion of a cylindrical reactor, a discharge port formed in a lower portion of the reactor, a wafer holding member on which a wafer is placed, and a gas distribution plate arranged between the wafer holding member and the gas supply port, wherein a separation distance between the gas distribution plate and the wafer holding member is set such that a cooling gas to cool the wafer is in a laminar flow state on a surface of the wafer or a surface of the wafer holding member.

A vapor-phase growth method according another embodiment of the present invention uses a vapor-phase growth apparatus including a gas supply port formed in an upper portion of a cylindrical reactor, a discharge port formed in a lower portion of the reactor, a wafer holding member on which a wafer is placed, and a gas distribution plate arranged between the wafer holding member and the gas supply port. In the vapor-phase growth method, the vapor-phase growth apparatus is used to cause a film forming gas to flow downward from the gas supply port into the reactor through the gas distribution plate to deposit a vapor-phase grown layer on the wafer, followed by causing a cooling gas to flow downward from the gas supply port into the reactor through the gas distribution plate to decrease a temperature of a wafer substrate. A separation distance between the gas distribution plate and the wafer holding member is set such that the cooling gas is in a laminar flow state on a surface of the wafer or a surface of the wafer holding member.

### BRIEF DESCRIPTION OF THE DRAWINGS

FIG. 1 is a vertical sectional view showing one configuration of a single-wafer-processing type epitaxial growth apparatus according to an embodiment.

FIG. 2 is a graph for explaining an outline of a film forming process sequence according to the embodiment.

FIG. 3 is a vertical sectional view of a single-wafer-processing type epitaxial growth apparatus according to the embodiment.

FIGS. 4A and 4B are pattern diagrams showing a gas flow of a cooling gas in the embodiment.

FIG. 5 is a vertical sectional view of a single-wafer-processing type epitaxial growth apparatus for explaining another embodiment.

### DETAILED DESCRIPTION OF THE EMBODIMENTS

Preferred embodiments of the present invention will be described below with reference to the accompanying drawings.

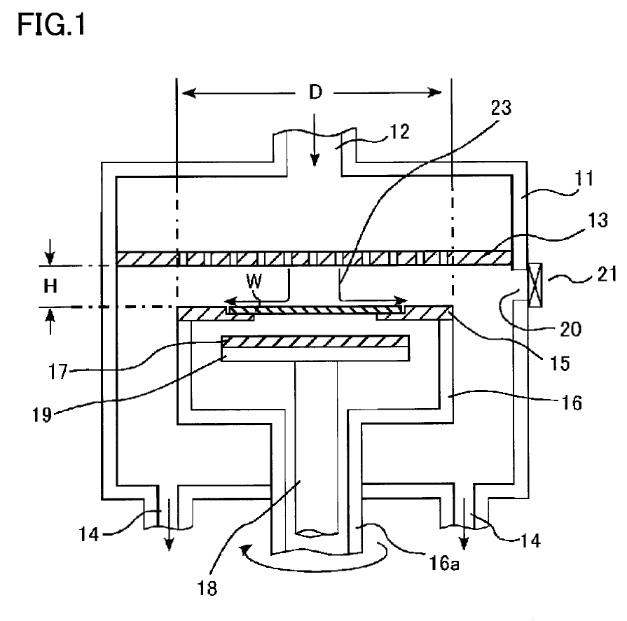

FIG. 1 shows a configuration of a single-wafer-processing type epitaxial growth apparatus according to one embodiment of the present invention. As shown in FIG. 1, the epitaxial growth apparatus includes a cylindrical hollow reactor 11, a gas supply port 12, and a gas distribution plate 13. The cylindrical hollow reactor 11 is made of, for example, stainless steel. The gas supply port 12 introduces a film forming gas into the reactor 11 from the top of the reactor 11. The gas distribution plate 13 creates a laminar flow of the film forming gas introduced from the gas supply port 12 and downstream flows the film forming gas onto a semiconductor wafer W placed downward as, for example, a layered flow. The epitaxial growth apparatus also includes a gas discharge port 14 which discharges a reaction product and a part of the film forming gas obtained after the reaction on the semiconductor wafer W surface or the like from the bottom portion of the reactor 11 to the outside of the reactor 11. The gas discharge port 14 is connected to a vacuum pump (not shown).

A rotator unit 16 and a heater 17 are arranged inside the reactor 11. The rotator unit 16 arranges an annular holder 15 of the wafer holding member to place and hold the semiconductor wafer Won the upper surface and rotates the annular holder 15. The heater 17 heats the semiconductor wafer W placed on the annular holder 15 with radiant heat. In this case, the rotator unit 16 is connected to a rotating device (not shown) having a rotating shaft 16a located thereunder, and the rotator unit 16 is attached so as to be rotatable at a high speed. The cylindrical rotating shaft 16a is connected to a vacuum pump to exhaust the hollow rotator unit 16, and the semiconductor wafer W may be brought into vacuum contact with the annular holder 15 by the suction. The rotating shaft 16a is rotatably inserted into the bottom portion of the reactor 11 through a vacuum seal member.

The heater 17 is fixed to the upper surface of a support table 19 of a support shaft 18 penetrating the inside of the rotating shaft 16a. For example, a push-up pin (not shown) to attach/detach the semiconductor wafer W to/from the annular holder 15 is formed in the support table 19. As the wafer holding member, a structure which contacts with a substantially entire rear surface of the semiconductor wafer W may be used in place of the annular holder. In this case, since a disk-like wafer substrate is generally placed on the wafer holding member, a planar shape of the edge of the wafer holding member is preferably circular, and the wafer holding member is preferably composed of a material which does not shield the radiant heat from the heater 17.

In the single-wafer-processing type epitaxial growth apparatus, the gas distribution plate 13 is a disk made of, for example, quartz glass and has a large number of gas discharge ports (or holes) formed therein. As shown in FIG. 1, H denotes a separation distance between an upper surface of the annular holder 15 and a lower surface of the gas distribution plate 13 which are parallel arranged to face each other. The separation distance H is set such that the cooling gas to cool the semiconductor wafer W is set in a laminar flow state on the surface of the semiconductor wafer W or the surface of the annular holder 15 serving as a wafer holding member.

Assuming that the outer diameter of the annular holder 15 is D, H/D≦⅕ is preferably satisfied. In this case, an inner circumference side of the annular holder 15 is counterboared, and the semiconductor wafer W is placed on the counterboard surface such that the rear surface of the semiconductor wafer W is in contact with the counterboared surface. Thus, a major surface of the semiconductor wafer W is located at a level which is almost equal to the level of the major surface of the annular holder 15.

As shown in FIG. 1, a wafer inlet/outlet port 20 and a gate valve 21 to remove or insert the semiconductor wafer W are formed in a side wall of the reactor 11, so that the semiconductor wafer W can be conveyed by a handling arm between, for example, a load lock chamber (not shown) and the reactor 11 which are connected to each other by the gate valve 21. In this case, for example, the handling arm made of synthetic quartz is inserted between the gas distribution plate 13 and the annular holder 15 serving as a wafer holding member. For this reason, the separation distance H must be equal to or larger than such a size that an insertion space for the handling arm can be secured.

Concrete examples of the separation distance H will be described below. When the semiconductor wafer W is a silicon wafer having, for example, a diameter of 200 mmφ, the outer diameter D of the annular holder 15 is set to 300 mmφ. When an insertion space required for a conveying operation performed by the handling arm is set to, for example, about 10 mm, a preferable range of the separation distance H is 20 mm to 60 mm.

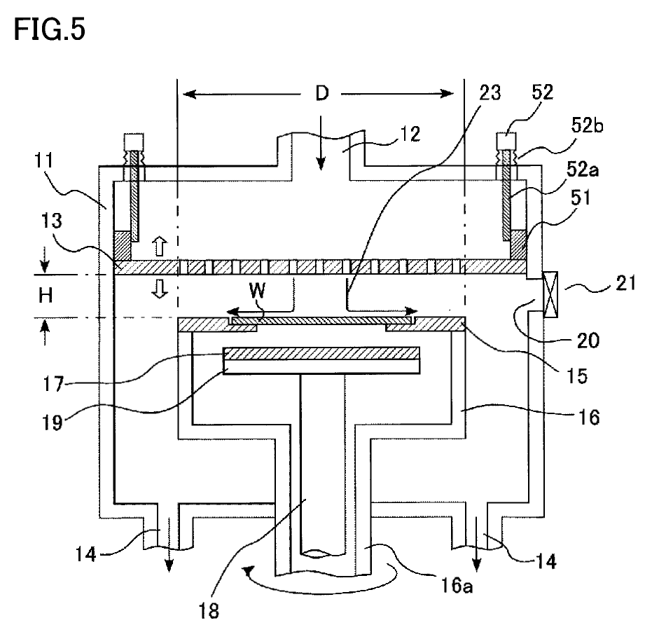

In this case, when the gas distribution plate 13 is enabled to be vertically moved as described later (see FIG. 5), a distance between the upper surface of the semiconductor wafer W and the lower surface of the gas distribution plate 13 in vapor-phase growth may be about 1 mm. Upon completion of the vapor-phase growth, when the gas distribution plate 13 is moved downward to set the distance to about 10 mm, a conveying operation of the wafer W by the handling arm can be performed. In this case, when the upper surface of the semiconductor wafer W and the lower surface of the gas distribution plate 13 are lower than 1 mm, the thickness of the vapor-phase-grown film varies, or defects occur. For this reason, the distance between the semiconductor wafer W surface and the lower surface of the gas distribution plate 13 is limited to 1 mm.

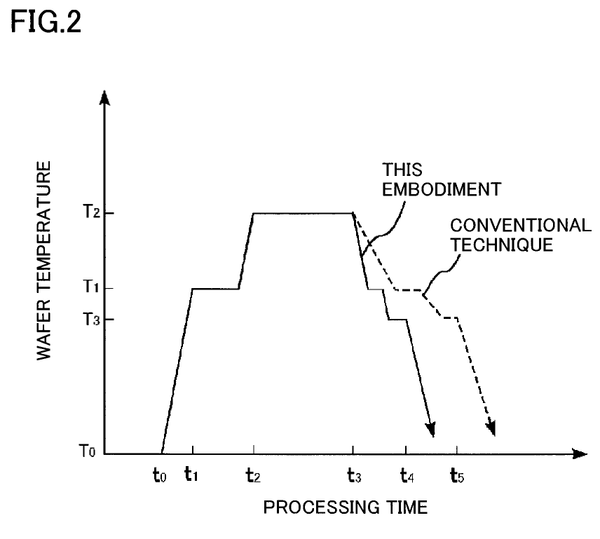

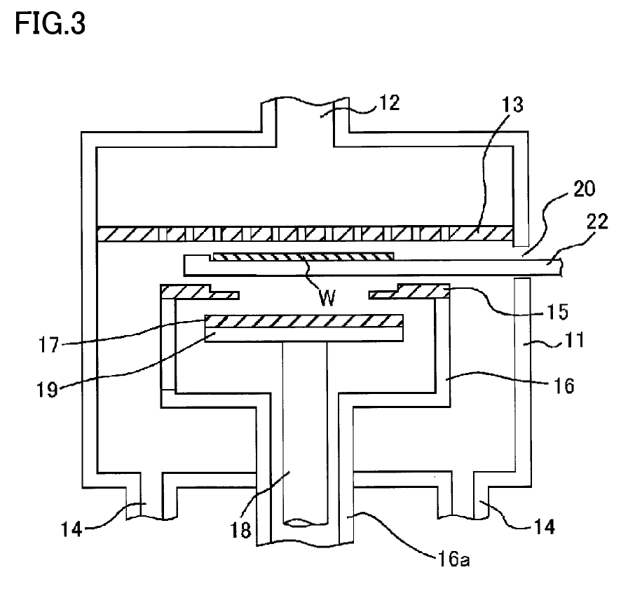

A film forming method for an epitaxial layer in the single-wafer-processing type epitaxial growth apparatus, an operation of the film forming method, and an effect in the embodiment will be described below with reference to FIGS. 1, 2, and 3. FIG. 2 is a graph for explaining an outline of a process sequence in film formation of the epitaxial layer. In FIG. 2, a processing time in a film forming cycle is plotted on the abscissa, and a wafer temperature of the semiconductor wafer W is plotted on the ordinate. FIG. 3 is a vertical sectional view of a single-wafer-processing type epitaxial growth apparatus showing a state in which the semiconductor wafer W is removed or inserted from/into the reactor 11.

At processing time to shown in FIG. 2, the wafer inlet/outlet port 20 is opened as shown in FIG. 3, the semiconductor wafer W in the load lock chamber in a reduced pressure state at room temperature To is placed on a handling arm 22 and inserted from the wafer inlet/outlet port 20 into the reactor 11. In this case, for example, the inside of the reactor 11 is in a nitrogen (N₂) gas atmosphere in a reduced pressure state, and a pressure in the reactor is set to be higher than that in the load lock chamber. In this manner, the inside of the reactor 11 is prevented from being contaminated by particles or the like from the load lock chamber. The semiconductor wafer W is placed on the annular holder 15 through, for example, a push-up pin (not shown), the handling arm 22 is returned to the load lock chamber, and the gate valve 21 is closed.

The semiconductor wafer W placed on the annular holder 15 is heated by the heater 17 waited to be heated to a first temperature T₁ of for preliminary heating and held at the temperature T₁ until the temperature becomes stable from processing time t₁. The N₂ gas is replaced with a hydrogen (H₂) gas during the preliminary heating, and the reactor 11 is evacuated to have a predetermined degree of vacuum.

A heating output of the heater 17 is increased to heat the semiconductor wafer W to a second temperature T₂ serving as an epitaxial growth temperature. When the temperature of the semiconductor wafer W becomes stable to a second temperature T₂ at processing time t₂, a predetermined film forming gas is supplied from the gas supply port 12 while rotating the rotator unit 16 at a desired speed, and an epitaxial layer is grown on the semiconductor wafer W surface at a predetermined degree of vacuum until processing time t₃.

For example, when a silicon epitaxial layer is to be grown, the first temperature T₁ is set to a desired temperature falling within the range of 500 to 900° C., and the second temperature T₂ is set to a desired temperature falling within the range of 1000 to 1200° C. SiH₄, SiH₂Cl₂, or SiHCl₃ is used as a source gas of the silicon, and B₂H₆, PH₃ or AsH₃ is used as a dopant gas. H₂ is generally used as a carrier gas. These gases serve as film forming gases.

In the reactor 11 in the growth of the silicon epitaxial layer, a desired pressure is set within the range of about 2×10³ Pa (15 Torr) to about 9.3×10⁴ Pa (700 Torr). A rotating speed of the rotator unit 16 is set to a desired rotating speed falling within the range of, for example, 300 to 1500 rpm.

At the processing time t₃ at which the epitaxial growth is ended, a decrease in temperature of the semiconductor wafer W on which the epitaxial layer is formed is started. In this case, the supply of the film forming gas and the rotation of the rotator unit 16 are stopped. With the semiconductor wafer W on which the epitaxial layer is formed being left on the annular holder 15, a heating output of the heater 17 is returned to the initial heating output to automatically adjust the temperature of the wafer W to the first temperature T₁.

At almost the same time, as shown in FIG. 1, a cooling gas 23 is made to flow from the gas supply port 12 into the reactor 11. The semiconductor wafer W is cooled by the cooling gas 23 converted to a laminar state by the gas distribution plate 13. In this case, the cooling gas 23 may be the same H₂ gas as the carrier gas serving as the film forming gas or a noble gas or an N₂ gas such as an argon gas or a helium gas. A pressure in the reactor 11 into which the cooling gas 23 is flowed is set to be almost equal to a pressure in growth of the epitaxial layer.

As described above, the gas distribution plate 13 and the annular holder 15 according to the embodiment are arranged such that a separation distance H between the gas distribution plate 13 and the annular holder 15 satisfies H/D≦⅕ in relation to an outer diameter D of the annular holder 15 as described above. For this reason, in the flow of the cooling gas 23 shown in FIG. 1, a laminar flow state in which a swirling current is rarely generated on the semiconductor wafer W is obtained as will be described later, so that cooling having high uniformity in the plane of the semiconductor wafer W can be performed. Even when thermal stress generated in the semiconductor wafer W in this cooling is reduced and a forcibly cooling rate by the cooling gas 23 is increased, crystal defects such as slip are suppressed from occurring in the semiconductor wafer W. This enables to shorten time required for a decrease in temperature of the semiconductor wafer W after the epitaxial growth.

For example, after the processing time t₃ shown in FIG. 2, a time interval between time at which the semiconductor wafer W has the second temperature T₂ serving as the epitaxial growth temperature and time at which the epitaxial growth temperature decreases to the first temperature T₁ serving as the preliminary heating temperature and becomes stable can be shortened to about ½ to ⅔ of a temperature in a conventional technique indicated by a dotted line in FIG. 2.

After the semiconductor wafer W is stabilized to the first temperature T₁, for example, the rear surface of the semiconductor wafer W is pushed up by, for example, the push-up pin and detached from the annular holder 15. In order to detach the semiconductor wafer W from the annular holder 15, not only the push-up pin, but also an electrostatic attaching scheme or Bernoulli chuck scheme which floats the semiconductor wafer W itself may be used. As shown in FIG. 3, the gate valve 21 is opened again to insert the handling arm 22 between the gas distribution plate 13 and the annular holder 15, and the semiconductor wafer W is placed on the handling arm. Thereafter, the push-up pin is in a lower state, the handling arm 22 is held at the insertion position until processing time t₄ at which the temperature of the semiconductor wafer W becomes a third temperature T₃ lower than the first temperature T₁ and is stabilized.

Thereafter, the handling arm 22 on which the semiconductor wafer W is placed is returned to the load lock chamber, and the gate valve 21 is closed. The temperature of the semiconductor wafer W returns to the room temperature To in the load lock chamber. In this case, as described at the processing time to, for example, the pressure in the reactor 11 set in a reduced pressure state of the N₂ gas atmosphere is higher than that of the load lock chamber.

As described above, a film forming cycle of an epitaxial layer to one semiconductor wafer is finished. Subsequently, a film is formed on another semiconductor wafer is performed according to the same process sequence as described above.

For a period from time at which the semiconductor wafer W has the first temperature T₁ to time at which the temperature of the semiconductor wafer W is stabilized at the third temperature T₃, the semiconductor wafer W is subjected to gas cooling by the cooling gas 23 on the handling arm 22. A time interval from time at which the semiconductor wafer W has the first temperature T₁ to time at which the temperature of the semiconductor wafer W decreases from the first temperature T₁ to the third temperature T₃ and is stabilized at the third temperature T₃ can be shortened to about ½ of the time interval in the conventional technique indicated by the dotted line shown in FIG. 2. A processing time t₅ shown in FIG. 2 is illustrated as a period from time at which the semiconductor wafer W has the first temperature T₁ to time at which the temperature of the semiconductor wafer W decreases to the third temperature T₃ and is stabilized at the third temperature T₃.

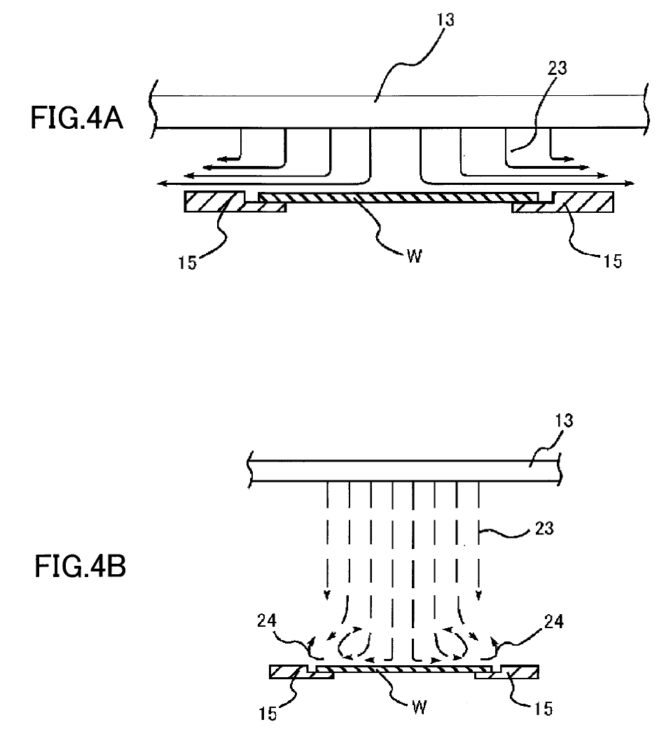

An operation of the structure according to the embodiment in gas cooling for the semiconductor wafer after the growth of the epitaxial layer will be described below with reference to the pattern diagram in FIGS. 4A and 4B. FIGS. 4A and 4B are pattern diagrams showing a gas flow of the cooling gas 23 between the gas distribution plate 13 of the single-wafer-processing type epitaxial growth apparatus and the annular holder 15 which holds the semiconductor wafer W. In this case, FIG. 4A shows an example in which the separation distance H described above satisfies H/D≦⅕ in relation to an outer diameter D (diameter of the wafer holding member) of the annular holder 15, and FIG. 4B shows an example in which the separation distance H satisfies H/D>⅕.

The cooling gas 23 in the reactor 11 forms a viscous flow, and the cooling gas 23 is introduced from the gas supply port 12 and become a laminar flow, for example, a layered flow through a gas discharge ports (or holes) of the gas distribution plate 13 and flows downward. In the configuration shown in FIG. 4A, the cooling gas 23 flowing downward is brought into contact with major surfaces of the semiconductor wafer W and the annular holder 15. Thereafter, the cooling gas 23 horizontally meanders along the major surfaces and flows while being kept in a laminar flow state. A crosscurrent does not occur at an outer circumference end of the cylindrical liner 15.

For this reason, in the plane of the semiconductor wafer W, a small quantity of the cooling gas 23 is in contact with the semiconductor wafer W at a uniform temperature, and heat radiation by heat exchange with the cooling gas 23 is uniformly performed. Heat radiation is not disturbed by occurrence of the crosscurrent at the outer circumference end of the annular holder 15, and the uniformity of the heat radiation is held. In decrease in temperature of the semiconductor wafer W, a temperature in the plane is kept uniform. Heat radiation by thermal radiation from the semiconductor wafer W surface is uniform in the plane.

In contrast to this, the configuration as shown in FIG. 4B causes the laminar flow state of the cooling gas 23 flowing downward to be disturbed on the major surfaces of the semiconductor wafer W and the annular holder 15 and easily broken. Thereafter, the cooling gas 23 is brought into contact with the major surfaces to horizontally meander and flow. In addition, a crosscurrent originally occurs at the outer circumference end of the annular holder 15. For these reasons, the cooling gas 23 disturbed in the laminar flow state and flowing downward very easily generates a swirling current 24 on the outer circumference side of the semiconductor wafer W or on the annular holder 15. When the value H₂/D increases, the swirling current 24 is also generated on a more inner circumference of the semiconductor wafer W.

Due to the generation of the swirling current 24, heat radiation by heat exchange with the cooling gas 23 is ununiformly performed in the plane of the semiconductor wafer W. In a decrease in temperature of the semiconductor wafer W, the uniformity of the in-plane temperature is damaged.

As described above, in the embodiment, a time required to decreases a temperature of a semiconductor wafer until the semiconductor wafer is conveyed out of the reactor after the end of the growth of the epitaxial layer, i.e., a time interval between the processing time t₃ and the processing time t₄ shown in FIG. 2 is considerably made smaller than a time interval between the third temperature T₃ and the processing time t₅ in the conventional technique. A throughput in film formation of the epitaxial layer can be easily increased. In this case, when a growth time (t₃ to t₂) of the epitaxial layer is shortened, a ratio of a temperature decrease time (t₄ to t₃) of the semiconductor wafer after the epitaxial growth to a film forming cycle increases to enhance an effect of shortening the temperature decrease time of the embodiment.

For example, in film formation of a silicon epitaxial layer having a film thickness of about 10 μm, a throughput increases by about 20%. When a desired film thickness of the epitaxial layer decreases and a growth rate of the epitaxial layer increases, an increase rate of the throughput further increases.

In the embodiment, a decrease in temperature of a semiconductor wafer after the growth of the epitaxial layer is stable more than that in the conventional technique, so that a fluctuation in cooling of the semiconductor wafer decreases. This considerably decreases a frequency of occurrence of wafer cracks when the semiconductor wafer is conveyed into the load lock chamber by the handling arm 22. In addition to the effect of reducing crystal defects such as a slip in the semiconductor wafer, a production yield in film formation of the epitaxial layer increases.

FIG. 5 is a vertical sectional view of a single-wafer-processing type epitaxial growth apparatus according to another embodiment of the present invention. As shown in FIG. 5, a gas distribution plate 13 is arranged such that the gas distribution plate 13 can be vertically moved (arrow in FIG. 5). More specifically, a member 51 which can be slid on the inner wall of the reactor 11 is arranged, and a connection member 52a extending from the drive mechanism 52 such as an air cylinder is connected to a surface opposing the inner wall. A bellows 52b is arranged above a portion between the connection member 52a and the drive mechanism.

In this case, a distance between the gas distribution plate 13 and the semiconductor wafer W can be adjusted from 1 mm to 60 mm by the drive mechanism 52. Even though the gas distribution plate 13 and the semiconductor wafer Ware approximated to each other, i.e., 1 mm, the epitaxial layer can be grown. When the semiconductor wafer W is removed or inserted, the distance between the gas distribution plate 13 and the semiconductor wafer W is preferably set to about 20 mm. The distance may also be about 10 mm.

In this manner, in film formation on the semiconductor wafer, the gas distribution plate 13 and the semiconductor wafer W are approximated to each other. When the semiconductor wafer W is removed or inserted, the distance between the gas distribution plate 13 and the semiconductor wafer W increases, the semiconductor wafer W can be removed or inserted.

In this case, the vertical movement of the gas distribution plate 13 can also be interlocked with movement of a mechanism which detaches the semiconductor wafer W from the annular holder 15 to remove or insert the semiconductor wafer W, for example, with movement of a push-up pin.

In the embodiment in FIG. 5, the distance between the gas distribution plate 13 and the semiconductor wafer W in the growth is ideally small. Actually, the distance is limited to about 1 mm. When the distance is adjusted to about 1 mm as described above, the annular holder 15 which holds the wafer W and the heater 17 can be cooperatively moved in place of the gas distribution plate 13.

According to the embodiments of the present invention described above, there are provided a vapor-phase growth apparatus and a vapor-phase growth method which can perform uniform cooling in a decrease in temperature of a wafer after the vapor-phase growth step and shortens a temperature decrease time to make it easy to realize a high throughput.

The preferable embodiments of the present invention are described above. However, the embodiments do not limit the present invention. A person skilled in the art can variously change and modify the concrete embodiments without departing from the spirit and scope of the present invention.

For example, in the embodiments, the single-wafer-processing type epitaxial growth apparatus may be connected to a conveying chamber of, for example, a cluster tool through a gate valve 21.

As the wafer holding member, not only an annular holder but also a so-called susceptor which has a heating mechanism and which is in contact with the entire rear surface of a semiconductor wafer may be used. When the annular holder (having an opening formed in the intermediate portion) is used, a removal flat plate is arranged on the opening. For example, the flat plate may be lifted up to make it possible to insert or remove a wafer into/from the reactor by a handling arm.

The gas supply port according to the present invention is not formed on not only the top face of the reactor, but also only an upper portion of the entire reactor. For example, the gas supply port maybe formed on, for example, the side surface of the reactor. Furthermore, the gas discharge port may be formed on not only the bottom surface of the reactor but also a lower portion of the entire reactor. For example, the gas discharge port may be formed on the side surface of the reactor.

The present invention is similarly applied to a single-wafer-processing type epitaxial growth apparatus having a structure in which a semiconductor wafer to be epitaxially grown is placed on an irrotational wafer holding member.

Although a wafer substrate on which a film is to be formed is typically a silicon wafer, a semiconductor substrate except for a silicon substrate such as a silicon oxide substrate may be used. As a thin film formed on the wafer substrate, a silicon film or a monocrystalline silicon film containing boron, phosphorous, or arsenic is most generally used. A monocrystalline silicon film partially containing a polysilicon film or another thin film, for example, a compound semiconductor film such as a GaAs film or a GaAlAs film can be applied without any problem.

In the present invention, the growth of a semiconductor is not limited to the epitaxial growth, but general vapor-phase growth, for example, MOCVD may be used. The epitaxial growth apparatus need not be of a single-wafer-processing type.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A vapor-phase growth apparatus comprising: a gas supply port formed in an upper portion of a cylindrical reactor; a discharge port formed in a lower portion of the cylindrical reactor; a wafer holding member on which a wafer is placed; and a gas distribution plate arranged between the wafer holding member and the gas supply port, wherein
a separation distance between the gas distribution plate and the wafer holding member is set such that a cooling gas to cool the wafer is in a laminar flow state on a surface of the wafer or a surface of the wafer holding member.

2. The apparatus according to claim 1, wherein
when the separation distance between the gas distribution plate and the wafer holding member is represented by H and a diameter of the wafer holding member is represented by D, H/D≦⅕ is satisfied.

3. The apparatus according to claim 2, wherein
a handling arm which removes or inserts the wafer from/into the reactor can be inserted between the lower surface of the gas distribution plate and the upper surface of the wafer holding member.

4. The apparatus according to claim 3, wherein
the wafer holding member is configured to be vertically movable.

5. The apparatus according to claim 4, wherein
vertical movement of the gas distribution plate is interlocked with movement of a mechanism which detach the wafer from the wafer holding member to remove or insert the wafer.

6. The apparatus according to claim 1, wherein
a distance between a lower surface of the gas distribution plate and an upper surface of the wafer holding member can be adjusted to not less than 1 mm and not more than 60 mm.

7. A vapor-phase growth method in which a vapor-phase growth apparatus, that includes: a gas supply port formed in an upper portion of a cylindrical reactor; a discharge port formed in a lower portion of the reactor; a wafer holding member on which a wafer is placed; and a gas distribution plate arranged between the wafer holding member and the gas supply port, is used to cause a film forming gas to flow downward from the gas supply port into the reactor through the gas distribution plate to deposit a vapor-phase grown layer on the wafer, followed by causing a cooling gas to flow downward from the gas supply port into the reactor through the gas distribution plate to decrease the temperature of the wafer, wherein
a separation distance between the gas distribution plate and the wafer holding member is set such that the cooling gas is in a laminar flow state on a surface of the wafer or a surface of the wafer holding member.

8. The method according to claim 7, wherein
a handling arm to remove or insert the wafer from/into the reactor is arranged between a lower surface of the gas distribution plate and an upper surface of the wafer holding member, and the wafer is removed or inserted from/into the reactor with the movement of the handling arm.

9. The method according to claim 8, wherein
the gas distribution plate and the wafer are approximated to each other when a film is formed on the wafer, and, when the wafer is removed or inserted, the distance between the gas distribution plate and the wafer increases to enable the wafer to be removed or inserted.

10. The method according to claim 9, wherein
the gas distribution plate can be vertically moved, and the gas distribution plate is interlocked with the wafer when the wafer is removed and inserted.
